(19) United States
(12) Patent Application Publication
(10) Pub. No.: US 2026/0135552 A1
(43) Pub. Date: May 14, 2026

(54) SEMICONDUCTOR DEVICE AND ELECTRONIC CONTROL SYSTEM

(71) Applicant: Renesas Electronics Corporation, Tokyo (JP)

(72) Inventor: Akihiro NAKAHARA, Tokyo (JP)

(21) Appl. No.: 19/371,423

(22) Filed: Oct. 28, 2025

(30) Foreign Application Priority Data
Nov. 12, 2024 (JP) 2024-197335

(51) Int. Cl. H03K 17/0812

(52) U.S. Cl. CPC H03K 17/08122; H03K 2217/0018; H03K 2217/0027

(57) ABSTRACT

A discharge transistor is formed on a semiconductor substrate, and controls a power transistor to the OFF state by short-circuiting a gate of the power transistor and a reference node when being controlled to the ON state. A reverse current detection circuit detects generation of a reverse current from a power output terminal toward a power supply terminal, and asserts a reverse current detection signal in a period in which a reverse current is generated. A switch control circuit controls a first switch to the ON state and a second switch to the OFF state during the negation period of the reverse current detection signal, and controls the first switch to the OFF state and the second switch to the ON state during the assertion period of the reverse current detection signal.

### CROSS-REFERENCE TO RELATED APPLICATIONS

The disclosure of Japanese Patent Application No. 2024-197335 filed on November 12, 2024 including the specification, drawings and abstract is incorporated herein by reference in its entirety.

### BACKGROUND

The present invention relates to a semiconductor device and an electronic control system, and for example, relates to a semiconductor device that supplies power to a load connected to the outside, and an electronic control system on which the semiconductor device is mounted.

There is disclosed a technique listed below.

[Patent Document 1] Japanese Unexamined Patent Application Publication No. 2018-11117

Patent Document 1 discloses a semiconductor device capable of preventing malfunction of a protection transistor when a reverse current is generated. The semiconductor device includes a power transistor and a protection circuit that short-circuits between a gate and a source of the power transistor using the protection transistor when a load is short-circuited. The protection circuit detects the load short circuit by a combination of the determination of the output voltage of the power transistor and the time determination by the timer. In the protection transistor, a parasitic bipolar transistor that is turned on when a reverse current flows through the power transistor is formed. Here, the protection circuit is configured not to erroneously detect the load short circuit when the reverse current is eliminated by controlling the timer based on the determination result of the output voltage.

### SUMMARY

For example, as disclosed in Patent Document 1, a semiconductor device including a power transistor and a protection transistor that short-circuits between a gate and a source of the power transistor when controlled to the ON state is known. In the power transistor that supplies power to the load, when the output voltage is higher than the power supply voltage, a reverse current is generated from the load toward the power supply terminal. This reverse current occurs, for example, when a capacitive load, an inductive load, or the like is driven. As another example, a ripple current generated by rectification when the load is a generator may also be a reverse current. When the power transistor is in the OFF state, such a reverse current flows through the body diode of the power transistor.

Here, a parasitic bipolar transistor that is turned on when a reverse current is generated can be formed in the protection transistor. The parasitic bipolar transistor in the ON state connects the gate of the power transistor to the power supply voltage. On the other hand, in order to turn on the power transistor in the OFF state, it is necessary to apply a boost voltage higher than the power supply voltage to the gate. However, when the parasitic bipolar transistor is in the ON state, it may be difficult to apply the boost voltage to the gate of the power transistor due to the connection to the power supply voltage described above. That is, there is a possibility that the power transistor cannot be turned on during the period in which the reverse current is generated.

Embodiments to be described below have been made in view of such circumstances, and other problems and novel features will be apparent from the description of the present specification and the accompanying drawings.

A semiconductor device according to an embodiment comprises an output transistor, a first switch, a second switch, a first control transistor, a reverse current detection circuit, and a switch control circuit. The output transistor is formed on the semiconductor substrate, is connected between the power supply terminal and the power output terminal, and supplies power to a load connected to the power output terminal when being controlled to the ON state. The first switch connects the power output terminal to the reference node. The second switch connects the power supply terminal to the reference node. The first control transistor is formed on a semiconductor substrate, and controls the output transistor to the OFF state by short-circuiting a gate of the output transistor and a reference node when being controlled to the ON state. The reverse current detection circuit detects generation of a reverse current from the power output terminal to the power supply terminal, and asserts a reverse current detection signal in a period in which the reverse current is generated. The switch control circuit controls the first switch to the ON state and the second switch to the OFF state during the negation period of the reverse current detection signal, and controls the first switch to the OFF state and the second switch to the ON state during the assertion period of the reverse current detection signal.

According to the embodiment, the output transistor can be turned on even in a period in which a reverse current is generated from the load toward the output transistor.

### BRIEF DESCRIPTION OF THE DRAWINGS

FIG. 1 is a circuit diagram illustrating a configuration example of a main part of a semiconductor device according to a first embodiment.

FIG. 2 is a schematic diagram illustrating a layout configuration example of the semiconductor device in FIG. 1.

FIG. 3 is a cross-sectional view illustrating a configuration example between A and A’ in FIG. 2.

FIG. 4A is a timing chart illustrating an operation example in a case where a reverse current does not flow in the semiconductor device illustrated in FIG. 1.

FIG. 4B is a timing chart illustrating an operation example in a case where a reverse current flows in the semiconductor device illustrated in FIG. 1.

FIG. 5 is a circuit block diagram illustrating a configuration example of an electronic control system (ECU) to which the semiconductor device illustrated in FIG. 1 is applied.

FIG. 6 is a schematic diagram illustrating a configuration example of a vehicle on which the electronic control system (ECU) illustrated in FIG. 5 is mounted.

FIG. 7 is a circuit diagram illustrating a configuration example of a main part of a semiconductor device according to a second embodiment.

FIG. 8 is a diagram illustrating an example of an operation mode provided in an ON/OFF control circuit in FIG. 7.

FIG. 9 is a timing chart illustrating a detailed operation example in each operation mode of the ON/OFF control circuit in FIGS. 7 and 8.

FIG. 10 is a circuit diagram illustrating a configuration example of a main part of a semiconductor device according to a third embodiment.

FIG. 11 is a circuit diagram illustrating a configuration example of a main part of a semiconductor device according to a fourth embodiment.

FIG. 12A is a circuit diagram illustrating a detailed configuration example including a parasitic element in a voltage selector switch illustrated in FIG. 11.

FIG. 12B is a circuit diagram illustrating a detailed configuration example including a parasitic element in a voltage selector switch illustrated in FIG. 10, which is a comparative example with respect to FIG. 12A.

FIG. 13 is a circuit diagram illustrating a configuration example of a semiconductor device as a comparative example.

FIG. 14 is a timing chart illustrating an operation example in a case where a reverse current flows in the semiconductor device illustrated in FIG. 13.

### DETAILED DESCRIPTION

In the following embodiments, when necessary for the sake of convenience, the description will be divided into a plurality of sections or embodiments, but unless otherwise specified, the sections or embodiments are not unrelated to each other, and one is in a relationship of some or all modifications, details, supplementary explanation, and the like of the other. In addition, in the following embodiments, when referring to the number of elements or the like (including number, numerical value, amount, range, and the like), the number of elements is not limited to a specific number unless otherwise specified or obviously limited to the specific number in principle, and the number of elements may be greater than or equal to or less than the specific number.

Furthermore, in the following embodiments, it goes without saying that the constituent elements (including element steps and the like) are not necessarily essential unless otherwise specified or considered to be obviously essential in principle. Similarly, in the following embodiments, when referring to the shape, positional relationship, and the like of the components and the like, it is assumed to include those substantially approximate or similar to the shape and the like unless otherwise specified or unless clearly considered to principle. The same applies to the above numerical values and ranges.

In the following embodiment, a p-channel metal oxide semiconductor field effect transistor (MOSFET) and an n-channel MOSFET are referred to as a pMOS transistor and an nMOS transistor, respectively. Hereinafter, embodiments of the present invention will be described in detail with reference to the drawings. In all the drawings for describing the embodiments, the same members are denoted by the same reference numerals in principle, and repeated description thereof will be omitted.

### First Embodiment

### Circuit Configuration of Semiconductor Device

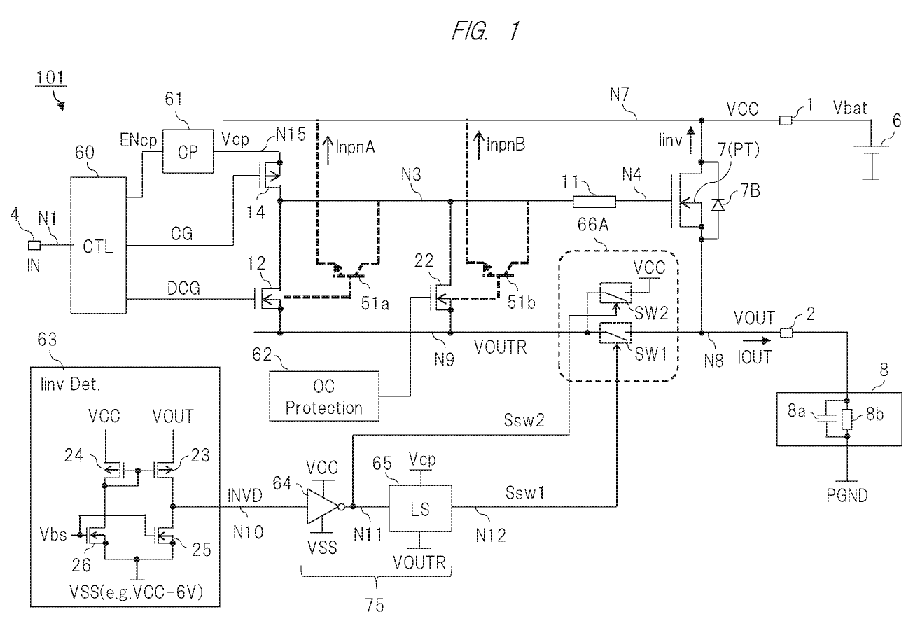

FIG. 1 is a circuit diagram illustrating a configuration example of a main part of a semiconductor device 101 according to a first embodiment. The semiconductor device 101 illustrated in FIG. 1 includes a power supply terminal 1, a power output terminal 2, a control input terminal 4, a power transistor (PT) 7, a gate resistance element 11, and various control circuits that control the power transistor (PT) 7.

The various control circuits include an ON/OFF control circuit 60, a charge pump (CP) circuit 61, a discharge transistor (control transistor) 12, a charge transistor 14, a protection transistor (control transistor) 22, and a protection circuit 62. In addition, the various control circuits include a voltage selector switch 66A, a reverse current detection circuit 63, and a switch control circuit 75, which will be described below in detail.

The power supply terminal 1 receives a battery voltage Vbat such as 12 V from an external battery 6. As a result, the power supply voltage VCC is supplied to the power supply terminal 1, that is, a power supply node N7. A load 8 is connected to the power output terminal 2, that is, a power output node N8. The load 8 includes a load 8a and a resistive load 8b connected in parallel. A ground power supply voltage PGND is supplied to one end of the load 8. In addition, an output voltage VOUT and an output current IOUT are generated at the power output terminal 2.

The power transistor (PT) 7 is also an output transistor connected between the power supply terminal 1 and the power output terminal 2. The power transistor (PT) 7 supplies power to the load 8 connected to the power output terminal 2 when controlled to the ON state. In this example, the power transistor (PT) 7 is an nMOS transistor. A source and a drain of the power transistor (PT) 7 are connected to the power output terminal 2 and the power supply terminal 1, respectively. In addition, the power transistor (PT) includes a body diode 7B having a commonly connected source and back gate as an anode and a commonly connected drain as a cathode.

The control input terminal 4 receives an ON/OFF control signal IN from the outside. The ON/OFF control signal IN is a signal for externally instructing on/off of the power transistor (PT) 7. The ON/OFF control circuit 60 exclusively controls on/off of the charge transistor 14 and the discharge transistor 12 according to the ON/OFF control signal IN. At this time, the ON/OFF control circuit 60 controls the charge transistor 14 using a charge control signal CG, and controls the discharge transistor 12 using a discharge control signal DCG.

In addition, the ON/OFF control circuit 60 controls the active state and the inactive state of the charge pump (CP) circuit 61 using a boost control signal ENcp. The charge pump (CP) circuit 61 generates a boost voltage Vcp higher than the power supply voltage VCC in the active state. The charge transistor 14 is, for example, a pMOS transistor. The discharge transistor 12 is, for example, an nMOS transistor.

For example, in a case where ON is instructed by the ON/OFF control signal IN, the ON/OFF control circuit 60 controls the charge transistor 14 to the ON state using the charge control signal CG. The charge transistor 14 in the ON state applies the boost voltage Vcp from the charge pump (CP) circuit 61 to a gate node N4 of the power transistor (PT) 7. Accordingly, the power transistor (PT) 7 is controlled to the ON state. More specifically, the charge transistor 14 applies the boost voltage Vcp to the node N3 serving as a drain node, and applies the boost voltage Vcp to the gate node N4 of the power transistor (PT) 7 via the gate resistance element 11.

On the other hand, in a case where the ON/OFF control signal IN instructs OFF, the ON/OFF control circuit 60 controls the discharge transistor (control transistor) 12 to the ON state using the discharge control signal DCG. The discharge transistor 12 in the ON state short-circuits the gate node N4 of the power transistor (PT) 7 and the power output node N8 serving as a source of the power transistor (PT) 7. As a result, the power transistor (PT) 7 is controlled to the OFF state. More specifically, the power output node N8 is connected to the reference node N9 via a voltage selector switch 66A to be described below. The discharge transistor 12 short-circuits the node N3 connected to the gate node N4 via the gate resistance element 11 and the reference node N9.

The protection transistor (control transistor) 22 is, for example, an nMOS transistor. Similarly to the discharge transistor 12, the protection transistor 22 short-circuits the gate node N4 of the power transistor (PT) 7 and the power output node N8 when controlled to the ON state. More specifically, the protection transistor 22 short-circuits the node N3 and the reference node N9. The protection circuit 62 detects a predetermined abnormality, and controls the protection transistor 22 to the ON state via, for example, a level shift circuit (not illustrated) when detecting the abnormality.

In this example, the protection circuit 62 is an overcurrent protection circuit that detects that an overcurrent (OC) has flowed through the power transistor (PT) 7 due to a load short circuit and controls the protection transistor 22 to the ON state. However, the present invention is not limited thereto, and the protection circuit 62 may be, for example, various circuits including an overtemperature protection circuit that detects occurrence of overtemperature in the power transistor (PT) 7 and controls the protection transistor 22 to the ON state. The protection transistor 22 turns off the power transistor (PT) 7 by short-circuiting the gate of the power transistor (PT) 7 and the reference node N9 in response to such predetermined abnormality detection.

### Device Configuration of Semiconductor Device

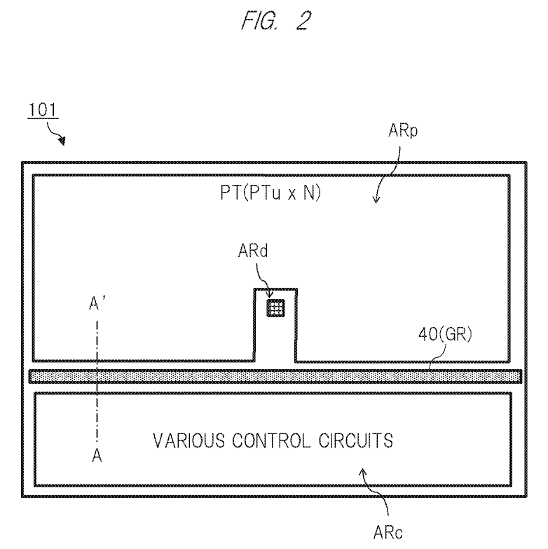

FIG. 2 is a schematic diagram illustrating a layout configuration example of the semiconductor device 101 in FIG. 1. The semiconductor device 101 illustrated in FIG. 2 includes a formation region ARp of the power transistor (PT) 7 and a formation region ARc of various control circuits. As described in FIG. 1, the various control circuits are circuits for controlling the power transistor (PT) 7. In this example, a guard ring (GR) 40 for isolation is provided between the formation region ARp and the formation region ARc. However, the semiconductor device 101 does not necessarily have the guard ring (GR) 40.

Specifically, the power transistor (PT) 7, that is, the output transistor includes a plurality of unit output transistors PTu connected in parallel to each other. Furthermore, in this example, a formation region ARd of the temperature detection diode is provided near the center of the formation region ARp of the power transistor (PT) 7. The temperature detection diode is used when the protection circuit 62 is an overtemperature protection circuit.

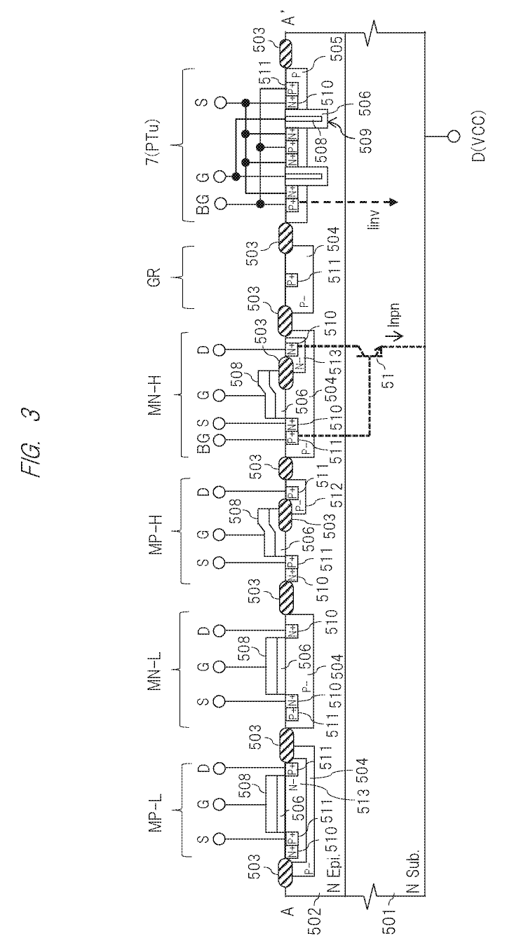

FIG. 3 is a cross-sectional view illustrating a configuration example between A and A’ in FIG. 2. In FIG. 3, an N-type epitaxial layer 502 is formed on an N-type semiconductor substrate 501. The various elements are formed using a diffusion layer, an oxide film, or the like disposed on the surface of the epitaxial layer 502. Here, as various elements, a unit output transistor PTu constituting the power transistor (PT) 7, a pMOS transistor MP-L and an nMOS transistor MN-L of low-voltage specifications, a pMOS transistor MP-H and an nMOS transistor MN-H of high-voltage specifications, and a guard ring GR are illustrated. The various elements are disposed adjacent to each other and separated by a thick oxide film 503 (LOCOS).

The pMOS transistors MP-L and MP-H and the nMOS transistors MN-L and MN-H are included in the various control circuits described above. The pMOS transistor MP-H and the nMOS transistor MN-H of the high-voltage specification have a withstand voltage of about 40 V, for example. On the other hand, the pMOS transistor MP-L and the nMOS transistor MN-L of the low-voltage specification have a withstand voltage of about 6 V, for example.

The unit output transistor PTu is constituted by a vertical nMOS transistor having a back surface of the semiconductor substrate 501 as a drain. Specifically, in the unit output transistor PTu, a Pbase diffusion layer 505 serving as a back gate (BG) is formed on the surface of the epitaxial layer 502. In the Pbase diffusion layer 505, an N⁺ type source (S) diffusion layer 510 and a P⁺ type power supply diffusion layer 511 for supplying power to a back gate (BG) are formed. The epitaxial layer 502 and the semiconductor substrate 501 serve as a drain (D). The power supply voltage VCC is supplied to the drain (D), that is, the back surface of the semiconductor substrate 501.

A trench 509 extending in the depth direction is formed in the epitaxial layer 502. A thin gate oxide film 506 and polysilicon 508 serving as a gate (G) are embedded in the trench 509. The source (S) diffusion layer 510 is formed at a position in contact with the sidewall of the trench 509. When a predetermined voltage is applied between the gate (G) and the source (S), a channel is formed at a position located on the sidewall of the trench 509 in the Pbase diffusion layer 505. As a result, a drive current flows from the back surface of the semiconductor substrate 501 toward the source (S) diffusion layer 510.

In the low-voltage specification pMOS transistor MP-L, a P⁻ type deep diffusion layer 504, that is, a p-well is formed on the surface of the epitaxial layer 502. An N⁻ type shallow diffusion layer 513, that is, an n-well is formed in the P⁻ type diffusion layer 504. In the N⁻ type diffusion layer 513, a P⁺ type source (S) diffusion layer 511 and drain (D) diffusion layer 511, and an N⁺ type power supply diffusion layer 510 for a back gate are formed. On the epitaxial layer 502 located between the source (S) diffusion layer 511 and the drain (D) diffusion layer 511, the polysilicon 508 serving as the gate (G) is formed via the thin gate oxide film 506.

In the nMOS transistor MN-L of the low-voltage specification, a P⁻ type deep diffusion layer 504, that is, a p-well is formed from the surface of the epitaxial layer 502. In the P⁻ type diffusion layer 504, an N⁺ type source (S) diffusion layer 510 and drain (D) diffusion layer 510, and a P⁺ type power supply diffusion layer 511 for a back gate are formed. On the epitaxial layer 502 located between the source (S) diffusion layer 510 and the drain (D) diffusion layer 510, the polysilicon 508 serving as the gate (G) is formed via the thin gate oxide film 506.

In the pMOS transistor MP-H of the high-voltage specification, a P⁺ type source (S) diffusion layer 511 and an N⁺ type power supply diffusion layer 510 for a back gate are formed on the surface of the epitaxial layer 502. On the other hand, on the drain (D) side, a P⁻ type deep diffusion layer 512 is formed from the surface of the epitaxial layer 502. A P⁺ type drain (D) diffusion layer 511 is formed in the P⁻ type diffusion layer 512.

In addition, on the epitaxial layer 502 located between the source (S) diffusion layer 511 and the drain (D) diffusion layer 511, the polysilicon 508 serving as the gate (G) is formed via the thin gate oxide film 506. However, unlike the pMOS transistor MP-L of the low-voltage specification, the gate oxide film 506 and the polysilicon 508 near the drain (D) ride over the thick oxide film 503 in order to realize a high withstand voltage.

In the nMOS transistor MN-H of the high-voltage specification, a P⁻ type deep diffusion layer 504, that is, a p-well is formed from the surface of the epitaxial layer 502. In the P⁻ type diffusion layer 504, an N⁺ type source (S) diffusion layer 510 and a P⁺ type power supply diffusion layer 511 for a back gate (BG) are formed. On the other hand, on the drain (D) side, an N⁻ type shallow diffusion layer 513 is formed from the surface of the epitaxial layer 502. In the N⁻ type diffusion layer 513, an N⁺ type drain (D) diffusion layer 510 is formed.

In addition, on the epitaxial layer 502 located between the source (S) diffusion layer 510 and the drain (D) diffusion layer 510, the polysilicon 508 serving as a gate (G) is formed via the thin gate oxide film 506. However, unlike the nMOS transistor MN-L of the low-voltage specification, the gate oxide film 506 and the polysilicon 508 near the drain (D) ride over the thick oxide film 503 in order to realize a high withstand voltage.

In the guard ring GR, a P⁻ type deep diffusion layer 504, that is, a p-well is formed from the surface of the epitaxial layer 502. A P⁺ type power supply diffusion layer 511 is formed in the P⁻ type diffusion layer 504. For example, a ground power supply voltage is applied to the P⁺ type power supply diffusion layer 511.

Here, in FIG. 1, when power is supplied to the load 8, for example, the output voltage VOUT may become higher than the power supply voltage VCC due to a decrease in the power supply voltage VCC. In this case, a reverse current Iinv flows from the power output terminal 2 toward the power supply terminal 1. When the power transistor (PT) 7 is in the OFF state, the reverse current Iinv flows to the body diode 7B formed between the source (S) and back gate (BG) and the drain (D) of the power transistor (PT) 7. FIG. 3 illustrates the reverse current Iinv in the unit output transistor PTu.

In addition, the discharge transistor 12 and the protection transistor 22 illustrated in FIG. 1 include the nMOS transistor MN-H of the high-voltage specification illustrated in FIG. 3. In the discharge transistor 12, an NPN parasitic bipolar transistor 51a can be formed. Similarly, an NPN parasitic bipolar transistor 51b can also be formed in the protection transistor 22. As illustrated in FIG. 3, the parasitic bipolar transistors 51a and 51b are formed as vertical parasitic bipolar transistors 51.

As illustrated in FIGS. 3 and 1, the parasitic bipolar transistor 51 operates with a back gate (BG) of the nMOS transistor MN-H and a source (S) connected to the back gate (BG) as a base. In addition, the parasitic bipolar transistor 51 operates with one of the drain (D) of the nMOS transistor MN-H and the back surface of the semiconductor substrate 501 as an emitter and the other as a collector. In this example, assuming that a high voltage is applied to the drain (D) of the nMOS transistor MN-H, the back surface of the semiconductor substrate 501 is an emitter.

By forming such a vertical parasitic bipolar transistor 51, as illustrated in FIG. 1, bases of the parasitic bipolar transistors 51a and 51b are connected to the power output terminal 2 via the voltage selector switch 66A. The emitters of the parasitic bipolar transistors 51a and 51b are connected to the power supply terminal 1 which is the back surface of the semiconductor substrate 501.

Here, when the reverse current Iinv flows through the body diode 7B of the power transistor (PT), the output voltage VOUT generated at the power output terminal 2 is clamped to be higher by about 0.6 V than the power supply voltage VCC supplied to the power supply terminal 1 by the forward voltage of the body diode 7B. As a result, the parasitic bipolar transistors 51a and 51b can be turned on since a forward bias of about 0.6 V is applied between the base and the emitter. The parasitic bipolar transistors 51a and 51b in the ON state connect the gate node N4 of the power transistor (PT) 7 to the power supply terminal 1.

On the other hand, in order to turn on the power transistor (PT) 7, it is necessary to apply the boost voltage Vcp higher than the power supply voltage VCC to the gate of the power transistor (PT) 7. However, when the parasitic bipolar transistors 51a and 51b are in the ON state, it may be difficult to apply the boost voltage Vcp to the gate of the power transistor (PT) 7 due to the connection to the power supply terminal 1 described above. That is, there is a possibility that the power transistor (PT) 7 cannot be turned on during the period in which the reverse current Iinv is generated. Therefore, in FIG. 1, a voltage selector switch 66A, a reverse current detection circuit 63, and a switch control circuit 75 are provided.

### Details of Voltage Selector Switch

In FIG. 1, the voltage selector switch 66A includes two switches SW1 and SW2. When controlled to the ON state, the switch (first switch) SW1 connects the power output terminal 2, that is, the power output node N8, to the reference node N9. When controlled to the ON state, the switch (second switch) SW2 connects the power supply terminal 1, that is, the power supply node N7, to the reference node N9.

The reverse current detection circuit 63 detects generation of the reverse current Iinv from the power output terminal 2 toward the power supply terminal 1. Then, the reverse current detection circuit 63 asserts a reverse current detection signal INVD in a period in which the reverse current Iinv is generated. Specifically, the reverse current detection circuit 63 includes, for example, pMOS transistors 23 and 24 and nMOS transistors 25 and 26 constituting a source input type differential amplifier circuit.

The gate of the pMOS transistor 24 is connected to the drain and is also connected to the gate of the pMOS transistor 23. The output voltage VOUT and the power supply voltage VCC are input to the sources of the pMOS transistor 23 and the pMOS transistor 24, respectively. An internal power supply voltage VSS is supplied to the sources of the two nMOS transistors 25 and 26. The internal power supply voltage VSS is a voltage lower than the power supply voltage VCC, for example, a voltage of “VCC-6 V”. The two nMOS transistors 25 and 26 respectively supply a common bias current based on a bias voltage Vbs from the drains to the two pMOS transistors 23 and 24.

With such a configuration, the reverse current detection circuit 63 functions as a comparator that compares the magnitudes of the output voltage VOUT and the power supply voltage VCC and detects the presence or absence of the generation of the reverse current Iinv. When the reverse current Iinv is flowing, since "VOUT>VCC", the gate-source voltage of the pMOS transistor 23 is larger than that of the pMOS transistor 24. As a result, the reverse current detection circuit 63 outputs the reverse current detection signal INVD at the assert level, here, the "H" level, to the output node N10. On the other hand, when the reverse current Iinv is not flowing, the reverse current detection circuit 63 outputs the reverse current detection signal INVD at the negated level, here, the "L" level.

The switch control circuit 75 controls the switch SW1 to the ON state and the switch SW2 to the OFF state during the negation period of the reverse current detection signal INVD. In addition, the switch control circuit 75 controls the switch SW1 to the OFF state and the switch SW2 to the ON state in the assertion period of the reverse current detection signal. Specifically, the switch control circuit 75 includes an inverter circuit 64 and a level shift circuit 65. In this example, it is assumed that the switches SW1 and SW2 are controlled to the ON state by signals having opposite polarities.

For example, the power supply voltage VCC and the internal power supply voltage VSS are supplied to the inverter circuit 64. The inverter circuit 64 controls on/off of the switch SW2 based on the reverse current detection signal INVD. Specifically, the inverter circuit 64 controls the switch SW2 with a voltage switching signal Ssw2 that is an inverted signal of the reverse current detection signal INVD. The switch SW2 is controlled to the ON state in a case where the voltage switching signal Ssw2 is at the "L" level, and furthermore, in a case where the reverse current detection signal INVD is at the assertion level. The "L" level and the "H" level of the voltage switching signal Ssw2 are the "VSS" level and the "VCC" level, respectively.

The level shift (LS) circuit 65 is supplied with, for example, a boost voltage Vcp generated at the output node N15 of the charge pump (CP) circuit 61 and a reference output voltage VOUTR generated at the reference node N9. The level shift circuit 65 controls on/off of the switch SW1 based on the reverse current detection signal INVD.

Specifically, the level shift circuit 65 generates the voltage switching signal Ssw1 to the switch SW1 by level-shifting the voltage switching signal Ssw2 to the switch SW2. Then, the level shift circuit 65 controls the switch SW1 with the voltage switching signal Ssw1. Contrary to the switch SW2, the switch SW1 is controlled to the ON state in a case where the voltage switching signal Ssw1 is at the "H" level and in a case where the reverse current detection signal INVD is at the negated level. The "L" level and the "H" level of the voltage switching signal Ssw1 are the "VOUTR" level and the "Vcp" level, respectively.

With the above configuration, when the reverse current detection signal INVD is at the assertion level, that is, when the reverse current Iinv is generated, the power supply voltage VCC can be applied to the bases of the parasitic bipolar transistors 51a and 51b. As a result, since the base-emitter voltage of the parasitic bipolar transistors 51a and 51b becomes 0 V, the parasitic bipolar transistors 51a and 51b can be controlled to the OFF state. As a result, even during the period in which the reverse current Iinv is generated, the boost voltage Vcp can be applied to the gate of the power transistor (PT) 7, and the power transistor (PT) 7 can be turned on.

More specifically, the power transistor (PT) 7 can be turned on even in a period in which the power transistor (PT) 7 is in the OFF state and the reverse current Iinv flows through the body diode 7B. That is, when the power transistor (PT) 7 is in the ON state, the reverse current Iinv flows through the channel of the power transistor (PT) 7. In this case, as a result of the output voltage VOUT being substantially clamped to the power supply voltage VCC, the parasitic bipolar transistors 51a and 51b are turned off. Therefore, the parasitic bipolar transistors 51a and 51b are not particularly problematic when the power transistor (PT) 7 is in the ON state.

### Operation of Semiconductor Device

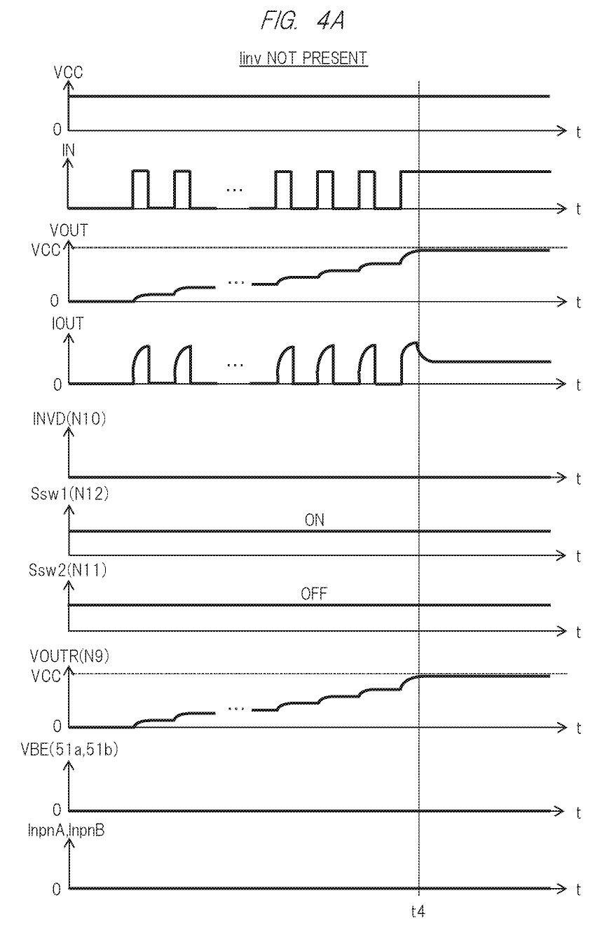

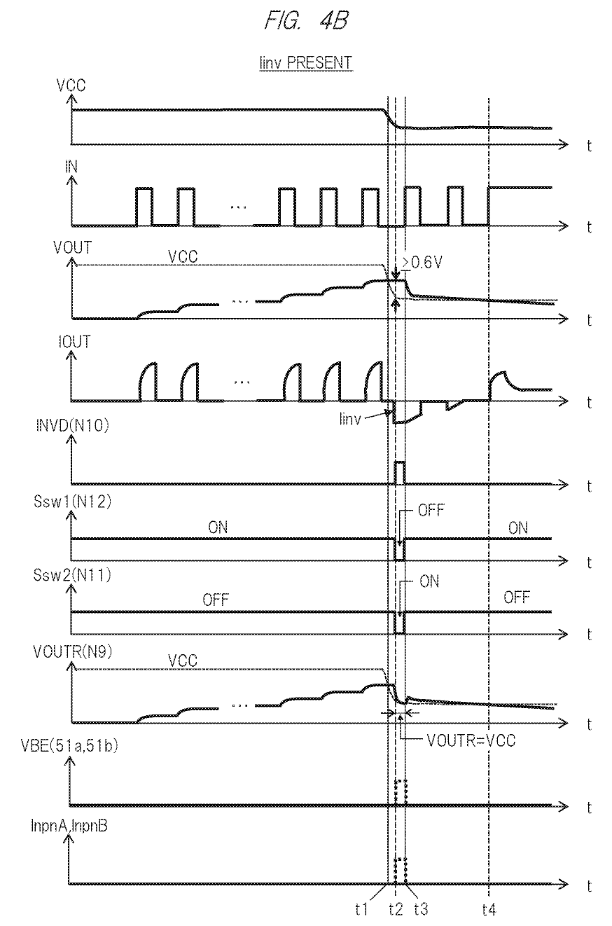

FIG. 4A is a timing chart illustrating an operation example in a case where the reverse current Iinv does not flow in the semiconductor device 101 illustrated in FIG. 1. For example, in a case where power is supplied to the load 8 as illustrated in FIG. 1, an inrush current flows when the load 8a is charged by controlling the power transistor (PT) 7 to the ON state. In order to suppress the inrush current, as illustrated in FIG. 4A, normally, an operation of periodically switching between on and off is performed using the ON/OFF control signal IN. Thus, the semiconductor device 101 charges the load 8a in a stepwise manner.

In a case where the ON/OFF control signal IN is at the "H" level, the charge transistor 14 is controlled to the ON state, and the discharge transistor 12 is controlled to the OFF state. As a result, the boost voltage Vcp higher than the power supply voltage VCC is applied to the gate node N4 of the power transistor (PT) 7. As a result, the power transistor (PT) 7 is controlled to the ON state to charge the load 8a.

On the other hand, when the ON/OFF control signal IN is at the "L" level, the charge transistor 14 is controlled to the OFF state, and the discharge transistor 12 is controlled to the ON state. As a result, the voltage of the gate node N4 of the power transistor (PT) 7 is lowered to the voltage of the power output node N8 which is the source node. As a result, the power transistor (PT) 7 is controlled to the OFF state and stops charging the load 8a. By repeating these steps, the load 8a is charged stepwise while limiting the maximum value of the inrush current. Then, in this example, the stepwise charging of the load 8a is completed at time t4.

In this example, the power supply voltage VCC and the output voltage VOUT maintain a relationship of "VOUT<VCC". Accordingly, the reverse current Iinv does not flow. Therefore, in the reverse current detection circuit 63, the pMOS transistor 23 is controlled to the OFF state through the differential amplification operation according to “VOUT<VCC”. As a result, the reverse current detection signal INVD is maintained at the "L" level, that is, the negated level.

The voltage switching signal Ssw2 becomes the "H" level, here, the OFF level according to the "L" level of the reverse current detection signal INVD. Accordingly, the switch SW2 maintains the OFF state. On the other hand, the voltage switching signal Ssw1 becomes the "H" level, here, the ON level according to the "H" level of the voltage switching signal Ssw2. Accordingly, the switch SW1 maintains the ON state. In addition, the reference output voltage VOUTR at the reference node N9 becomes equal to the output voltage VOUT by maintaining the switch SW1 in the ON state.

In addition, when the reverse current Iinv is not flowing, a base-emitter voltage VBE of the two parasitic bipolar transistors 51a and 51b is at least a reverse bias. As a result, two parasitic currents InpnA and InpnB respectively flowing through the two parasitic bipolar transistors 51a and 51b are 0 A. Here, for simplification of description, the reversely biased base-emitter voltage VBE is illustrated as 0 V.

The above is the operation when the output current IOUT flowing through the power transistor (PT) 7 is smaller than the threshold current. At this time, the protection circuit 62, specifically, the overcurrent protection circuit maintains the protection transistor 22 in the OFF state by outputting a signal at the "L" level. On the other hand, when the output current IOUT becomes larger than the threshold current due to the load short circuit, the protection circuit 62 outputs a signal at the "H" level to turn on the protection transistor 22. As a result, the power transistor (PT) 7 is protected by being turned off, and stops charging of the load 8a.

FIG. 4B is a timing chart illustrating an operation example in a case where the reverse current Iinv flows in the semiconductor device 101 illustrated in FIG. 1. In FIG. 4B, unlike the case of FIG. 4A, the state of "VOUT>VCC" occurs at time t1 as a result of the decrease in the power supply voltage VCC occurring during the off-period of the power transistor (PT) 7. When the power transistor (PT) 7 is in the OFF state, no channel is formed, and thus the reverse current Iinv flows through the body diode 7B. Specifically, the reverse current Iinv starts to flow, for example, at time t2 when “VOUT-VCC” exceeds the forward voltage of the body diode 7B, for example, about 0.6 V.

Here, the reverse current detection circuit 63 detects the generation of the reverse current Iinv and asserts the reverse current detection signal INVD to the "H" level. That is, in the reverse current detection circuit 63, the pMOS transistor 23 is controlled to the ON state through the differential amplification operation according to “VOUT>VCC”. As a result, reverse current detection signal INVD becomes the "H" level. In practice, the reverse current detection signal INVD can be at the "H" level from time t1 when "VOUT>VCC".

The voltage switching signal Ssw2 becomes the "L" level, here, the ON level according to the "H" level of the reverse current detection signal INVD. Accordingly, the switch SW2 is turned on. On the other hand, the voltage switching signal Ssw1 becomes the "L" level, here, the OFF level according to the "L" level of the voltage switching signal Ssw2. Accordingly, the switch SW1 is turned off.

When the switch SW2 is controlled to the ON state, the reference output voltage VOUTR generated at the reference node N9 becomes equal to the power supply voltage VCC. As a result, since the base-emitter voltage VBE becomes 0 V, the parasitic bipolar transistors 51a and 51b can maintain the OFF state. As a result, the parasitic currents InpnA and InpnB can also maintain 0 A.

Thereafter, at time t3, the ON/OFF control signal IN transitions to the "H" level. At this time, since the parasitic bipolar transistors 51a and 51b are in the OFF state, the boost voltage Vcp can be applied to the gate node N4 of the power transistor (PT) 7. As a result, the power transistor (PT) 7 is turned on. In response to this, the reverse current Iinv flowing through the body diode 7B flows through the channel of the power transistor (PT) 7 having a low channel resistance.

As the reverse current Iinv flows through the channel of the power transistor (PT) 7, the output voltage VOUT approaches the power supply voltage VCC. Accordingly, the reverse current Iinv also decreases. When the reverse current Iinv does not flow, and actually "VOUT<VCC" is satisfied, the reverse current detection circuit 63 negates the reverse current detection signal INVD to the "L" level. In response to this, the switch SW2 is turned off when the voltage switching signal Ssw2 transitions to the "H" level, that is, the OFF level. On the other hand, the switch SW1 is turned on when the voltage switching signal Ssw1 transitions to the "H" level, that is, the ON level.

By turning on the switch SW1, the reference output voltage VOUTR generated at the reference node N9 becomes equal to the output voltage VOUT. In addition, since the charge of the load 8a is discharged through the resistive load 8b, the output voltage VOUT will eventually become lower than the power supply voltage VCC. As a result, the reverse current Iinv becomes zero and returns to the normal state. In FIG. 4B, in order to simplify the description, the reverse current detection signal INVD is negated at time t3.

### Difference from Semiconductor Device (Comparative Example)

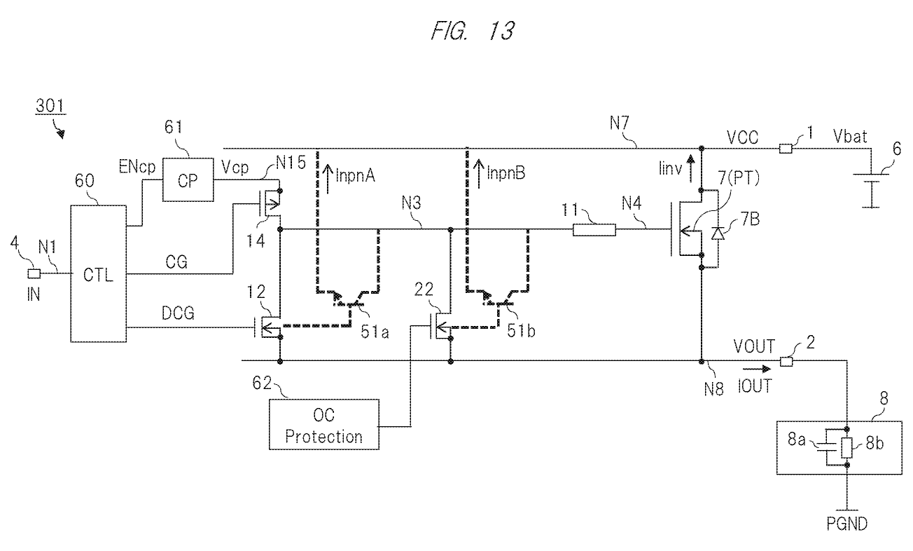

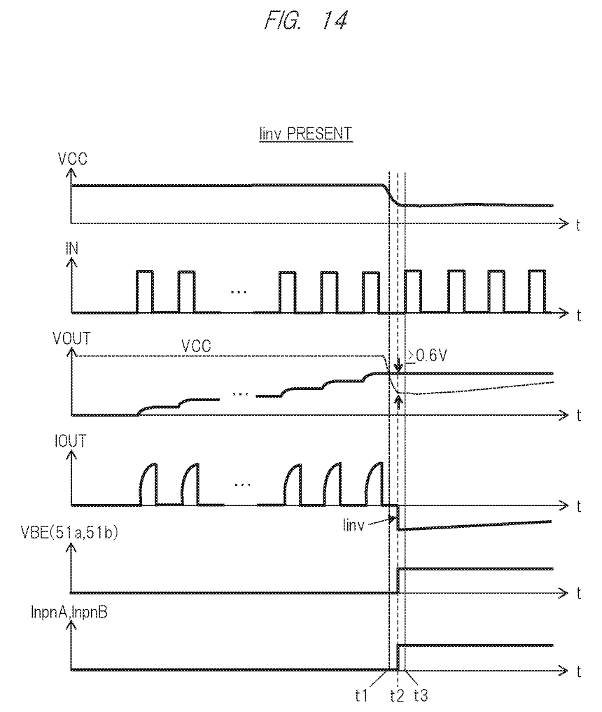

FIG. 13 is a circuit diagram illustrating a configuration example of a semiconductor device 301 as a comparative example. FIG. 14 is a timing chart illustrating an operation example in a case where the reverse current Iinv flows in the semiconductor device 301 illustrated in FIG. 13. A semiconductor device 301 as a comparative example illustrated in FIG. 13 is different from the configuration example illustrated in FIG. 1 in the following points. As a first difference, the voltage selector switch 66A, the reverse current detection circuit 63, and the switch control circuit 75 are not provided. As a second difference, with the deletion of the voltage selector switch 66A, the sources of the discharge transistor 12 and the protection transistor 22 are connected to the power output node N8.

When such a configuration is used, as illustrated in FIG. 14, the parasitic bipolar transistors 51a and 51b are turned on at time t2 when the reverse current Iinv is generated. As a result, even when the ON/OFF control signal IN is switched to the "H" level at the subsequent time t3, the power transistor (PT) 7 cannot be turned on. That is, the power transistor (PT) 7 cannot be turned on until the reverse current Iinv stops flowing.

Furthermore, the period during which the reverse current Iinv is flowing can be prolonged because the power transistor (PT) 7 cannot be turned on. Accordingly, a period during which the power transistor (PT) 7 cannot be turned on can be prolonged. On the other hand, using the configuration example of FIG. 1, the power transistor (PT) 7 can be turned on at time t3, and as a result, the period during which the reverse current Iinv flows can also be shortened.

### Application Example to Electronic Control System (ECU)

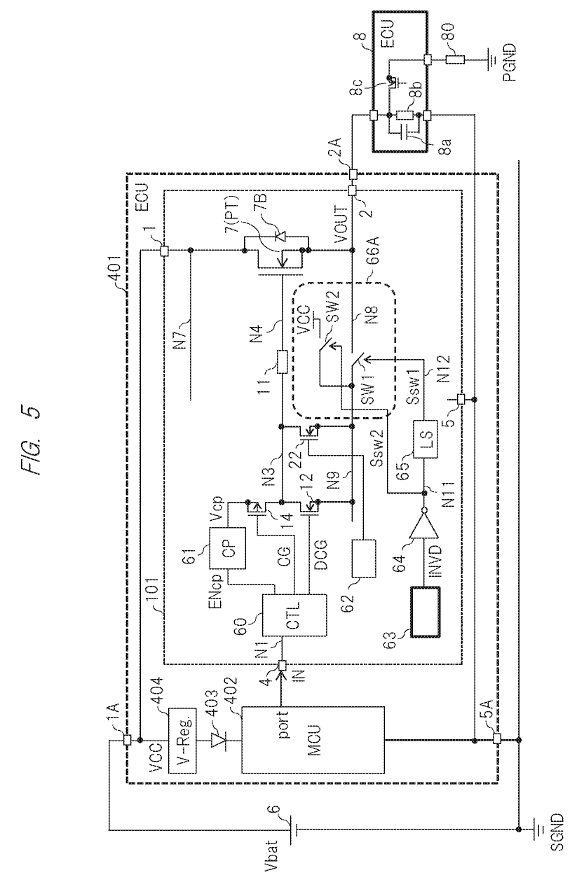

FIG. 5 is a circuit block diagram illustrating a configuration example of an electronic control system (ECU) 401 to which the semiconductor device 101 illustrated in FIG. 1 is applied. The electronic control system (ECU) 401 illustrated in FIG. 5 includes a power supply regulator 404 and a diode 403, and an ECU control device 402, here, a microcontroller unit (MCU), in addition to the semiconductor device 101 illustrated in FIG. 1. The electronic control system (ECU) 401 can include a wiring board or the like on which these components are mounted.

The electronic control system (ECU) 401 also includes a power supply terminal 1A, a ground power supply terminal 5A, and a power output terminal 2A. The battery 6 is connected between the power supply terminal 1A and the ground power supply terminal 5A. A load 8 is connected to the power output terminal 2A. In this example, the load 8 is another electronic control unit (ECU). The electronic control unit serving as the load 8 includes a load 8a, a resistive load 8b, a power switch 8c, and the like. Another load 80 is connected between the power output terminal of the electronic control unit, which is also the power output terminal of the power switch 8c, and the ground power supply voltage PGND.

The battery voltage Vbat is input to the power supply terminal 1A. The power supply regulator 404 receives the power supply voltage VCC obtained at the power supply terminal 1A, and generates a low-voltage power supply voltage for the ECU control device 402. The generated power supply voltage is supplied to the ECU control device 402 via the diode 403. In addition, a ground power supply voltage SGND of the battery 6 is supplied to one end of the ECU control device 402 via the ground power supply terminal 5A. The diode 403 functions to protect the ECU control device 402, and prevents a reverse current from flowing through the ECU control device 402 when the battery 6 is reversely connected, for example.

An output port of the ECU control device 402 is connected to the control input terminal 4 of the semiconductor device 101. The ECU control device 402 outputs an ON/OFF control signal IN for instructing on/off of the power transistor (PT) 7 to the semiconductor device 101. The semiconductor device 101 controls power supply to the load 8 based on the ON/OFF control signal IN from the control input terminal 4. At this time, for example, even when the reverse current Iinv as described above occurs due to a decrease in the battery voltage Vbat, the power supply to the semiconductor device 101 and the load 8 can be controlled by the ON/OFF control signal IN from the ECU control device 402.

Note that a power supply voltage VCC from the power supply terminal 1A of the electronic control system (ECU) 401 is supplied to the power supply terminal 1 of the semiconductor device 101. The power output terminal 2 of the semiconductor device 101 is connected to the power output terminal 2A of the electronic control system (ECU) 401. In addition, the semiconductor device 101 includes a ground power supply terminal 5. The ground power supply terminal 5 is supplied with a ground power supply voltage SGND via the ground power supply terminal 5A of the electronic control system (ECU) 401.

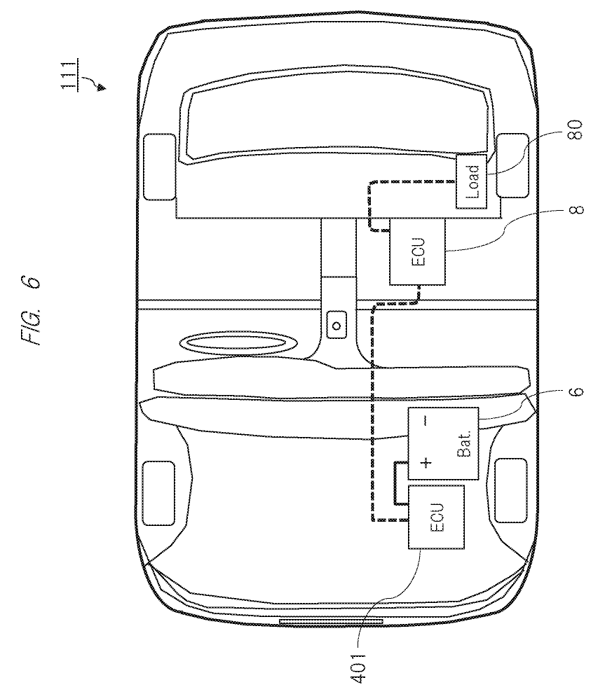

FIG. 6 is a schematic diagram illustrating a configuration example of a vehicle 111 equipped with the electronic control system (ECU) 401 illustrated in FIG. 5. The vehicle 111 is, for example, an automobile. As illustrated in FIG. 5, a vehicle 111 illustrated in FIG. 6 is mounted with a battery 6, an electronic control system 401, and loads 8 and 80. The electronic control system 401 and the load 8, and the load 8 and the load 80 are each connected by a wire harness. The ground power supply voltage PGND illustrated in FIG. 5 is connected to, for example, a housing of the vehicle 111.

### Supplemental Items

For example, in FIG. 4B, the case where the reverse current Iinv occurs in the period in which the load 8a is charged in a stepwise manner, that is, in the period before time t4 has been described. Here, it is assumed that the reverse current Iinv is generated in the period after the stepwise charging of the load 8a is completed, that is, in the period after time t4.

First, when the power transistor (PT) 7 is controlled to the ON state based on the ON/OFF control signal IN at the "H" level, the reverse current Iinv flows to the channel of the power transistor (PT) 7 instead of the body diode 7B. As a result, since the output voltage VOUT is substantially clamped to the power supply voltage VCC, the parasitic bipolar transistor 51 maintains the OFF state. That is, in this case, the problem caused by the parasitic bipolar transistor 51 does not particularly occur.

On the other hand, when the power transistor (PT) 7 is controlled to the OFF state based on the ON/OFF control signal IN at the "L" level, the reverse current Iinv flows to the body diode 7B. As a result, parasitic bipolar transistor 51 may be turned on. The parasitic bipolar transistor 51 in the ON state can fix the voltage of the node N3 connected to the gate of the power transistor (PT) 7 to the power supply voltage VCC.

However, at this time, the output voltage VOUT higher than the power supply voltage VCC is applied to the source of the power transistor (PT) 7 along with the reverse current Iinv. Therefore, the power transistor (PT) 7 can maintain the OFF state as instructed based on the ON/OFF control signal IN. That is, in this case, even if the parasitic bipolar transistor 51 is turned on, no particular problem occurs.

In addition, when the ON/OFF control signal IN transits from the "L" level to the "H" level in a state where the reverse current Iinv is flowing, the switch SW1 is controlled to the OFF state and the switch SW2 is controlled to the ON state by the reverse current detection circuit 63 and the switch control circuit 75, respectively. As a result, the parasitic bipolar transistor 51 is controlled to the OFF state. As a result, the boost voltage Vcp can be applied to the gate of the power transistor (PT) 7 via the charge transistor 14 controlled to the ON state. That is, the power transistor (PT) 7 can be turned on as instructed based on the ON/OFF control signal IN.

### Main Effects of First Embodiment

As described above, the semiconductor device 101 according to the first embodiment includes the reverse current detection circuit 63, the voltage selector switch 66A, and the switch control circuit 75 in addition to the output transistor and the control transistor that controls the output transistor to the OFF state. The switch control circuit 75 connects the source and the back gate of the control transistor to the power supply terminal 1 using the voltage selector switch 66A in a period in which the reverse current Iinv is generated from the load 8 toward the output transistor. As a result, the parasitic bipolar transistor 51 formed in the control transistor can be controlled to the OFF state, and the output transistor can be turned on even in a period in which a reverse current is generated.

### Second Embodiment

### Circuit Configuration and Operation of Semiconductor Device

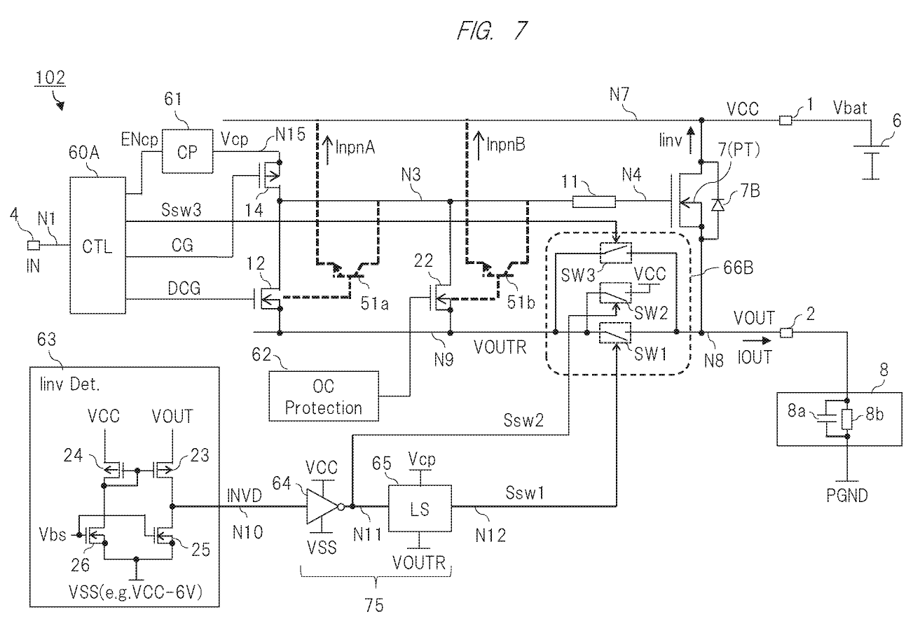

FIG. 7 is a circuit diagram illustrating a configuration example of a main part of a semiconductor device 102 according to a second embodiment. The semiconductor device 102 illustrated in FIG. 7 is different from the configuration example illustrated in FIG. 1 in the following points. As a first difference, the voltage selector switch 66B includes a switch SW3 in addition to the switches SW1 and SW2. The switch (third switch) SW3 is connected in parallel with the switch (first switch) SW1. As a second difference, an ON/OFF control circuit 60A different from that in the case of FIG. 1 is provided. The ON/OFF control circuit 60A controls on/off of the switch SW3 in addition to controlling the discharge transistor 12 and the charge transistor 14 and controlling the active state and the inactive state of the charge pump (CP) circuit 61.

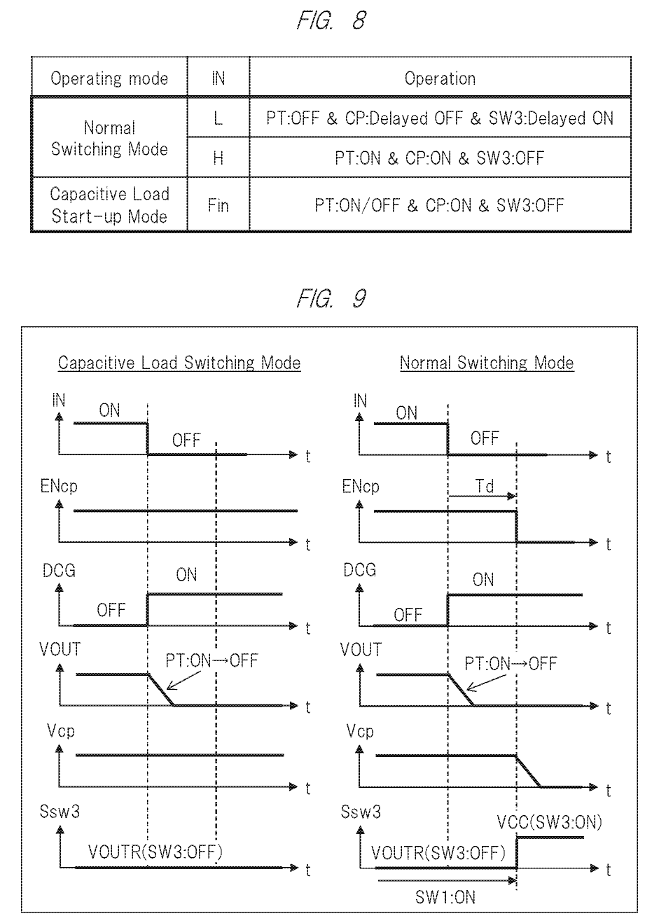

FIG. 8 is a diagram illustrating an example of an operation mode provided in the ON/OFF control circuit 60A in FIG. 7. The ON/OFF control circuit 60A operates in a startup mode of a capacitive load or a normal switching mode. The ON/OFF control circuit 60A operates in the startup mode of the capacitive load in a period in which the load 8a is charged stepwise, that is, in a period before time t4 in FIGS. 4A and 4B. On the other hand, the ON/OFF control circuit 60A operates in the normal switching mode in a period after the gradual charging of the load 8a is completed, that is, a period after time t4.

In the capacitive load start-up mode, the ON/OFF control circuit 60A receives the ON/OFF control signal IN that changes with the frequency Fin, and controls on/off of the power transistor (PT) 7 based on the ON/OFF control signal IN. In addition, the ON/OFF control circuit 60A controls the charge pump (CP) circuit 61 to be constantly in the active state using the boost control signal ENcp. Further, the ON/OFF control circuit 60A constantly controls the switch SW3 to the OFF state using the voltage switching signal Ssw3.

The charge pump (CP) circuit 61 is provided, as its main purpose, to generate a boost voltage Vcp necessary for controlling the power transistor (PT) 7 to the ON state. Meanwhile, the semiconductor device 102 is also required to reduce power consumption. Therefore, during a period during which the ON/OFF control signal IN is at the "L" level, it is originally desired to control the charge pump (CP) circuit 61 to an inactive state. However, if the active state and the inactive state of the charge pump (CP) circuit 61 are frequently switched during the period of charging the load 8a in a stepwise manner, the switching speed of the power transistor (PT) 7 may decrease.

Specifically, at the node N15 where the boost voltage Vcp is generated, discharge may occur according to the transition of the ON/OFF control signal IN to the "L" level. In this case, when the ON/OFF control signal IN transitions to the "H" level thereafter, a certain time is required to charge the node N15 to the desired boost voltage Vcp. As a result, the effective switching speed of the power transistor (PT) 7 may be reduced. Therefore, in the startup mode of the capacitive load, the charge pump (CP) circuit 61 is constantly controlled to the active state.

On the other hand, in the normal switching mode, the ON/OFF control circuit 60A receives the ON/OFF control signal IN at the "H" level or the "L" level, and controls the power transistor (PT) 7 to the ON state or the OFF state. Here, the ON/OFF control circuit 60A desirably controls the charge pump (CP) circuit 61 to an inactive state using the boost control signal ENcp during a period in which the ON/OFF control signal IN at the "L" level is input.

However, in the configuration example illustrated in FIGS. 1 and 7, the switch SW1 is controlled to the ON state by the boost voltage Vcp generated at the node N15. When the charge pump (CP) circuit 61 is inactivated, the voltage at the node N15 may drop to the level of the power supply voltage VCC supplied to the power supply node N7, for example, due to a leakage current of the charge transistor 14. As a result, the switch SW1 can be controlled to the OFF state according to the transition of the ON/OFF control signal IN to the "L" level.

When the switch SW1 is in the OFF state, the reference node N9, which is the source of the discharge transistor 12, is disconnected from the power output node N8, which is the source of the power transistor (PT) 7. As a result, a situation in which the charge at the gate node N4 of the power transistor (PT) 7 is not pulled out by the discharge transistor 12, that is, a situation in which the power transistor (PT) 7 cannot be turned off may occur.

Therefore, in the normal switching mode, when the turn-off of the power transistor (PT) 7 is instructed by the ON/OFF control signal IN, the ON/OFF control circuit 60A controls the charge pump (CP) circuit 61 in the active state to the inactive state through a predetermined delay time (Td). In addition, the ON/OFF control circuit 60A controls the charge pump (CP) circuit 61 to an inactive state and controls the switch SW3 to be turned on using the power supply voltage VCC.

FIG. 9 is a timing chart illustrating a detailed operation example in each operation mode of the ON/OFF control circuit 60A in FIGS. 7 and 8. First, in the startup mode of the capacitive load, the ON/OFF control circuit 60A maintains the boost control signal ENcp at the active level, here, the "H" level even when the ON/OFF control signal IN transitions to the "L" level. As a result, as long as the reverse current Iinv does not occur, the switch SW1 maintains the ON state by applying the desired boost voltage Vcp.

In addition, the ON/OFF control circuit 60A controls the discharge transistor 12 to the ON state by outputting the discharge control signal DCG at the ON level, here, the "H" level according to the transition of the ON/OFF control signal IN to the "L" level. In the discharge transistor 12 in the ON state, since the switch SW1 maintains the ON state, the power transistor (PT) 7 can be turned off. In addition, the ON/OFF control circuit 60A maintains the OFF state of the switch SW3 by outputting the voltage switching signal Ssw3 at the "L" level, here, the level of the reference output voltage VOUTR. However, the switch SW3 may be in the ON state.

On the other hand, in the normal switching mode, when the ON/OFF control signal IN transitions to the "L" level, the ON/OFF control circuit 60A causes the boost control signal ENcp to transition from the active level to the inactive level, here, the "L" level through the predetermined delay time Td. At the delay time Td, the switch SW1 maintains the ON state. Therefore, when the discharge transistor 12 is turned on according to the discharge control signal DCG at the "H" level, the charge of the gate of the power transistor (PT) 7 can be extracted to the source of the power transistor (PT) 7.

The power transistor (PT) 7 is turned off in response to the turn-on of the discharge transistor 12. Accordingly, the output voltage VOUT decreases to the level of the ground power supply voltage PGND, for example. The length of the delay time Td is determined based on the time required for turning off the power transistor (PT) 7, the decreasing speed of the output voltage VOUT, or the like. On the other hand, the switch SW1 cannot always maintain the ON state in a period after the delay time Td, that is, a period after the charge pump (CP) circuit 61 is controlled to the inactive state.

Therefore, the ON/OFF control circuit 60A turns on the switch SW3 using the voltage switching signal Ssw3 at the "H" level after a predetermined delay time Td. At this time, the output voltage VOUT and the reference output voltage VOUTR are substantially at the level of the ground power supply voltage PGND. Therefore, the "H" level of the voltage switching signal Ssw3 may be the level of the power supply voltage VCC. After the switch SW3 is turned on, the OFF state of the power transistor (PT) 7 can be maintained by a low-impedance discharge path through the discharge transistor 12 and the switch SW3.

### Main Effects of Second Embodiment

As described above, by using the method of the second embodiment, effects similar to the various effects described in the first embodiment can be obtained. Furthermore, since the charge pump (CP) circuit 61 can be controlled to the inactive state in an unnecessary period, for example, a period in which the load 8 does not need to be operated, the power consumption of the semiconductor device 102 can be reduced.

### Third Embodiment

### Specific Example of Voltage Selector Switch

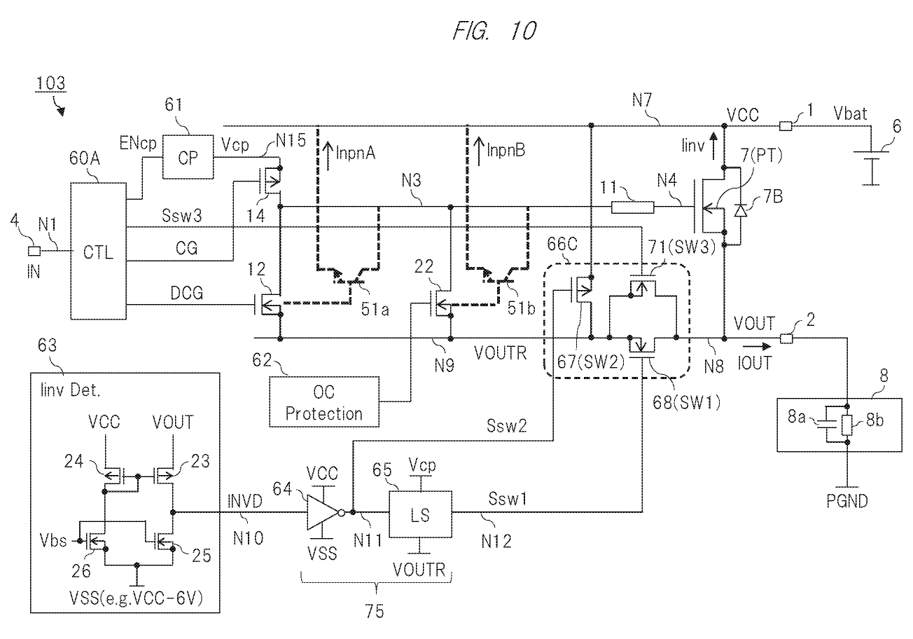

FIG. 10 is a circuit diagram illustrating a configuration example of a main part of a semiconductor device 103 according to a third embodiment. The semiconductor device 103 illustrated in FIG. 10 has a configuration similar to the configuration illustrated in FIG. 7. However, unlike the case of FIG. 7, FIG. 10 illustrates a more detailed configuration example of the voltage selector switch 66C. The voltage selector switch 66C includes three switches SW1 to SW3 as in the case of FIG. 7.

The switch SW1 includes an nMOS transistor (first FET) 68. The switch SW2 includes a pMOS transistor (second FET) 67. The switch SW3 includes an nMOS transistor (third FET) 71. In each of the two nMOS transistors 68 and 71, the source and the back gate are connected to the reference node N9, and the drain is connected to the power output node N8. In the pMOS transistor 67, the source and the back gate are connected to the power supply node N7, and the drain is connected to the reference node N9.

In this case, the nMOS transistor 68 is controlled to the ON state by applying the boost voltage Vcp to the gate, and is controlled to the OFF state by applying the reference output voltage VOUTR to the gate. The nMOS transistor 71 is controlled to the OFF state by applying the reference output voltage VOUTR to the gate. In addition, on the premise that the reference output voltage VOUTR is substantially at the level of the ground power supply voltage PGND, the nMOS transistor 71 is controlled to the ON state by applying the power supply voltage VCC to the gate. The pMOS transistor 67 is controlled to the ON state by applying the internal power supply voltage VSS to the gate, and is controlled to the OFF state by applying the power supply voltage VCC to the gate.

### Main Effects of Third Embodiment

As described above, by using the method of the third embodiment, effects similar to the various effects described in the second embodiment can be obtained. Further, each of the three switches SW1 to SW3 can be realized by one MOS transistor. As a result, overhead of the circuit area can be reduced.

### Fourth Embodiment

### Modification of Voltage Selector Switch

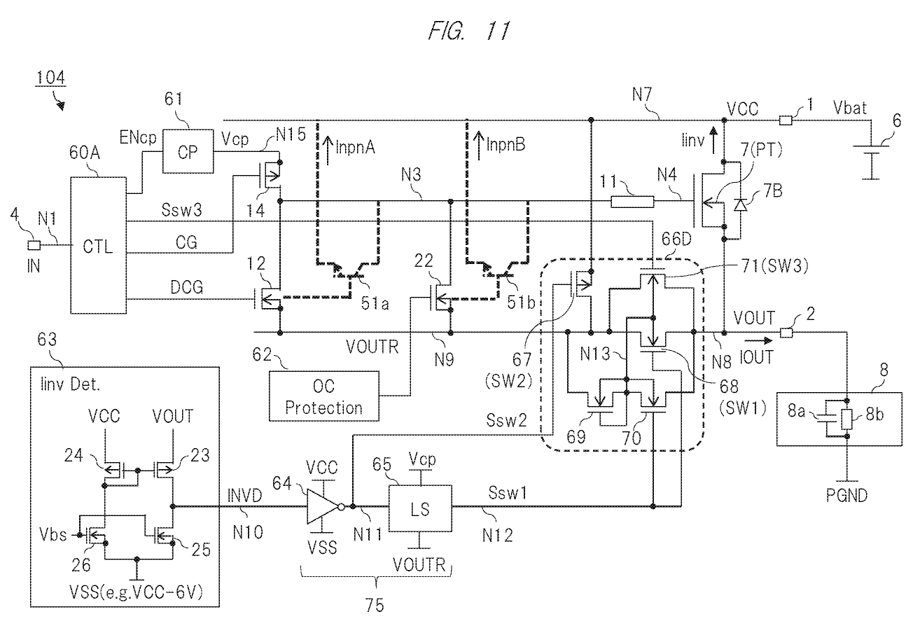

FIG. 11 is a circuit diagram illustrating a configuration example of a main part of a semiconductor device 104 according to a fourth embodiment. The semiconductor device 104 illustrated in FIG. 11 has the same configuration as the configuration illustrated in FIG. 10 except for a voltage selector switch 66D. The voltage selector switch 66D includes two nMOS transistors 69 and 70 in addition to the two nMOS transistors 68 and 71 and the one pMOS transistor 67 substantially similar to the case of FIG. 10. However, unlike the case of FIG. 10, the sources of the two nMOS transistors 68 and 71 are not connected to the back gate.

The two nMOS transistors 69 and 70 are connected in series between the power output terminal 2 and the reference node N9, and are connected in parallel with the nMOS transistor 68. In the nMOS transistor (fourth FET) 69, one of a source and a drain is connected to the reference node N9, the other is connected to the intermediate node N13, and a gate is connected to the intermediate node N13. In the nMOS transistor (fifth FET) 70, one of a source and a drain is connected to the intermediate node N13, and the other is connected to the power output terminal 2.

Then, on/off of the nMOS transistor (first FET) 68 and the nMOS transistor (fifth FET) 70 is commonly controlled by the switch control circuit 75. In addition, the back gates of the four nMOS transistors 68, 69, 70, and 71 are all connected to the intermediate node N13. By using such a configuration, it is possible to prevent a current flowing through the back gate of the nMOS transistor 68 which is the switch SW1 or the nMOS transistor 71 which is the switch SW3. That is, the parasitic bipolar transistors that can also be formed in the four nMOS transistors 68, 69, 70, and 71 can be controlled to the OFF state.

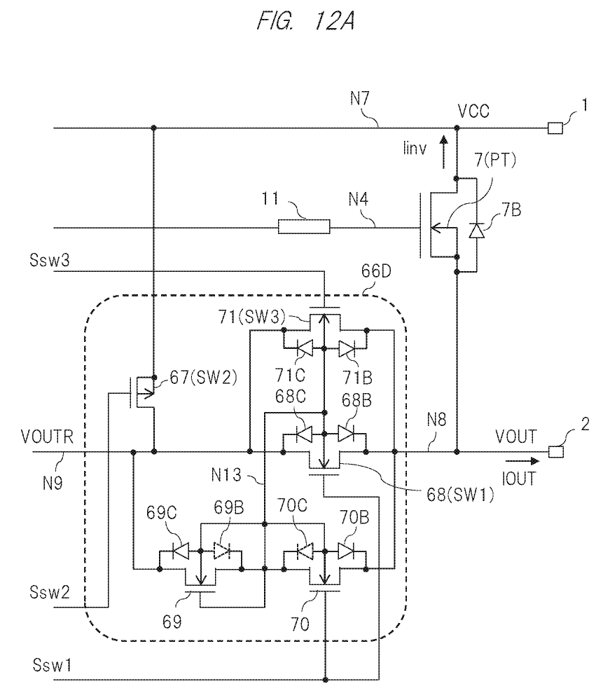

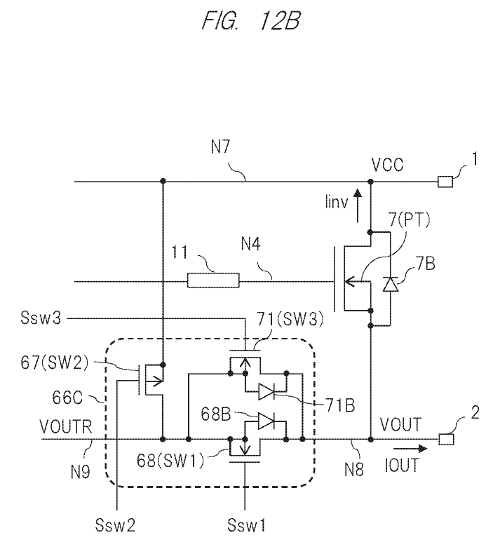

FIG. 12A is a circuit diagram illustrating a detailed configuration example including a parasitic element in the voltage selector switch 66D illustrated in FIG. 11. FIG. 12B is a circuit diagram illustrating a detailed configuration example including a parasitic element in the voltage selector switch 66C illustrated in FIG. 10, which is a comparative example with respect to FIG. 12A. First, in FIG. 12B, the nMOS transistor 68 more specifically includes a body diode 68B between a back gate and a drain. In addition, since the back gate and the source are short-circuited, the body diode between the back gate and the source is ignored. Similarly, the nMOS transistor 71 also has a body diode 71B between the back gate and the drain.

Here, for example, it is assumed that when the pMOS transistor 67 is in the ON state and the two nMOS transistors 68 and 71 are in the OFF state, the voltage of the power output node N8 rapidly decreases due to a load short circuit, a surge, or the like. In this case, a current flows from the power supply node N7 toward the power output terminal 2 via the body diodes 68B and 71B of the two nMOS transistors 68 and 71.

As a result, the parasitic bipolar transistors formed in the two nMOS transistors 68 and 71 are turned on, which may destroy the two nMOS transistors. That is, similarly to the case of the discharge transistor 12 and the protection transistor 22 illustrated in FIG. 10 and the like, NPN parasitic bipolar transistors that operate on the basis of the reference node N9 are also formed in the two nMOS transistors 68 and 71. When a current flows through the body diodes 68B and 71B instead of the channels of the two nMOS transistors 68 and 71, the parasitic bipolar transistor can be turned on by forward biasing between the base and the emitter.

On the other hand, in FIG. 12A, in the four nMOS transistors 68, 69, 70, and 71, the back gate is connected to the intermediate node N13. Therefore, the nMOS transistor 68 includes the two body diodes 68B and 68C both having the back gate as the anode. Similarly, the remaining three nMOS transistors 69, 70, and 71 also have a total of six body diodes 69B, 69C, 70B, 70C, 71B, and 71C. However, since the two body diodes 69B and 70C are in a short-circuit state due to wiring, they are ignored.

The two body diodes 68C and 71C whose cathodes are connected to the reference node N9 block the current flowing from the reference node N9 to the power output terminal 2 via the two body diodes 68B and 71B when the two nMOS transistors 68 and 71 are in the OFF state, respectively. Furthermore, in the nMOS transistor 69, the body diode 69C whose cathode is connected to the reference node N9 blocks the current flowing through the three body diodes 68B, 70B, and 71B via the intermediate node N13 which is a back gate.

Note that on/off of the nMOS transistor 70 is controlled by the same voltage switching signal Ssw1 as the nMOS transistor 68. Then, in a case where the nMOS transistor 70 is in the ON state, the voltage of the intermediate node N13, that is, the back gate voltages of the four nMOS transistors 68, 69, 70, and 71 are determined as the output voltage VOUT.

With such a configuration, for example, when the three nMOS transistors 68, 70, and 71 are in the OFF state, even when the voltage of the power output node N8 rapidly decreases due to a load short circuit, a surge, or the like, a current does not flow from the power supply node N7 through the three body diodes 68B, 70B, and 71B. As a result, in the three nMOS transistors 68, 70, and 71, since the parasitic bipolar transistor can be maintained in the OFF state, destruction that can be caused by the parasitic bipolar transistor in the ON state can be prevented.

The operation of the semiconductor device 104 illustrated in FIG. 11 is similar to the operation illustrated in FIGS. 4A and 4B except for the operation of the voltage selector switch 66D. To briefly describe the difference, first, as illustrated in FIG. 4A, in a case where the load 8a is charged in a stepwise manner in a state where the reverse current Iinv does not flow, the pMOS transistor 67, which is the switch SW2, is controlled to the OFF state. On the other hand, the nMOS transistor 68 which is the switch SW1 and the nMOS transistor 70 which shares a gate with the nMOS transistor 68 are controlled to the ON state. As a result, the voltages at the reference node N9 and the intermediate node N13 become substantially equal to the output voltage VOUT.

In the nMOS transistor 69, the voltage of the intermediate node N13, that is, substantially the output voltage VOUT is applied to the gate and the back gate, and the reference output voltage VOUTR, that is, substantially the output voltage VOUT is applied to the source. As a result, the nMOS transistor 69 is controlled to the OFF state. As a result, the voltage of the intermediate node N13 is substantially determined to be at the level of the output voltage VOUT by the nMOS transistor 70 in the ON state.

Furthermore, as described with reference to FIGS. 8 and 9, the nMOS transistor 71 is fixed to the OFF state, for example, in a period in which the load 8a is charged in a stepwise manner. Since the reverse current Iinv does not flow, the parasitic bipolar transistors 51a and 51b of the discharge transistor 12 and the protection transistor 22 maintain the OFF state as in the case of FIG. 4A.

On the other hand, as illustrated in FIG. 4B, in a case where the reverse current Iinv flows in the process of charging the load 8a in a stepwise manner, the pMOS transistor 67 which is the switch SW2 is controlled to the ON state at time t2. On the other hand, the nMOS transistor 68, which is the switch SW1, and the nMOS transistor 70 sharing a gate with the nMOS transistor 68 are controlled to the OFF state. As a result, the reference output voltage VOUTR generated at the reference node N9 becomes equal to the power supply voltage VCC. In addition, the reference node N9 is disconnected from the power output node N8.

Note that the voltage of the intermediate node N13, that is, the back gate voltage of the four nMOS transistors 68, 69, 70, and 71 is the reference output voltage VOUTR, that is, a voltage between the power supply voltage VCC and the output voltage VOUT higher than the power supply voltage VCC. Since the voltage of the intermediate node N13 is applied to the source of the nMOS transistor 70 and the voltage switching signal Ssw1 at the level of the reference output voltage VOUTR is applied to the gate thereof, the nMOS transistor is controlled to the OFF state. As a result, the series circuit including the two nMOS transistors 69 and 70 can separate the reference node N9 from the power output node N8 together with the nMOS transistor 68.

As a result, as in the case of FIG. 4B, the parasitic bipolar transistors 51a and 51b are controlled to the OFF state since the base-emitter voltage VBE becomes 0 V. Accordingly, parasitic currents InpnA and InpnB do not flow. As a result, the power transistor (PT) 7 can be turned on by applying the boost voltage Vcp to the gate of the power transistor (PT) 7. That is, ON/OFF control of the power transistor (PT) 7 can be performed based on the ON/OFF control signal IN.

### Main Effects of Fourth Embodiment

As described above, by using the method of the fourth embodiment, effects similar to the various effects described in the second embodiment can be obtained. Furthermore, unlike the system of the third embodiment, in the voltage selector switch 66D, the parasitic bipolar transistor formed in each nMOS transistor can be maintained in the OFF state. As a result, it is possible to prevent destruction of each nMOS transistor that can be caused by the parasitic bipolar transistor in the ON state. That is, the reliability of the semiconductor device 104 can be enhanced.

Although the invention made by the present inventors has been specifically described based on the embodiments, the present invention is not limited to the above embodiments, and various modifications can be made without departing from the gist of the present invention. For example, the above-described embodiments have been described in detail in order to describe the present invention in an easy-to-understand manner, and are not necessarily limited to those having all the described configurations. A part of the configuration of one embodiment can be replaced with the configuration of another embodiment, and the configuration of another embodiment can be added to the configuration of one embodiment. In addition, it is possible to add, delete, and replace other configurations for a part of the configuration of each embodiment.

What is claimed is:

1. A semiconductor device comprising:
an output transistor formed on a semiconductor substrate, and connected between a power supply terminal and a power output terminal, and configured to supply power to a load connected to the power output terminal when being controlled to the ON state;
a first switch configured to connect the power output terminal to a reference node;
a second switch configured to connect the power supply terminal to the reference node;
a first control transistor formed on the semiconductor substrate, and configured to control the output transistor to the OFF state by short-circuiting a gate of the output transistor and the reference node when being controlled to the ON state;
a reverse current detection circuit configured to detect generation of a reverse current from the power output terminal toward the power supply terminal and assert a reverse current detection signal in a period in which the reverse current is generated; and
a switch control circuit configured to control the first switch to the ON state and the second switch to the OFF state in a negation period of the reverse current detection signal, and control the first switch to the OFF state and the second switch to the ON state in an assertion period of the reverse current detection signal.

2. The semiconductor device according to claim 1,
wherein the output transistor comprises an n-channel MOSFET having the power output terminal and the power supply terminal as a source and a drain, respectively,
wherein the first switch comprises a first FET that is an n-channel MOSFET, and
wherein the second switch comprises a second FET that is a p-channel MOSFET.

3. The semiconductor device according to claim 2, further comprising:
a fourth FET and a fifth FET connected in series between the power output terminal and the reference node, connected in parallel with the first FET, and both of which are n-channel MOSFETs,
wherein, in the fourth FET, one of a source and a drain is connected to the reference node, the other is connected to an intermediate node, a gate is connected to the intermediate node,
wherein, in the fifth FET, one of a source and a drain is connected to the intermediate node, and the other is connected to the power output terminal,
wherein the first FET and the fifth FET are commonly controlled to be turned on and off by the switch control circuit, and
wherein back gates of the first FET, the fourth FET, and the fifth FET are connected to the intermediate node.

4. The semiconductor device according to claim 1, further comprising:
an ON/OFF control circuit configured to control on/off of the first control transistor based on an ON/OFF control signal for externally instructing on/off of the output transistor; and
a charge pump circuit configured to generate a boost voltage higher than a power supply voltage applied to the power supply terminal in an active state.

5. The semiconductor device according to claim 4, further comprising:
a third switch connected in parallel with the first switch,
wherein the ON/OFF control circuit further controls an active state and an inactive state of the charge pump circuit, and on/off of the third switch,
wherein the switch control circuit controls the first switch to the ON state using the boost voltage, and
wherein the ON/OFF control circuit controls the charge pump circuit in the active state to an inactive state through a predetermined delay time when turn-off of the output transistor is instructed by the ON/OFF control signal, and controls the third switch to the ON state using the power supply voltage.

6. The semiconductor device according to claim 5,
wherein the output transistor comprises an n-channel MOSFET having the power output terminal and the power supply terminal as a source and a drain, respectively,
wherein the first switch comprises a first FET that is an n-channel MOSFET,
wherein the second switch comprises a second FET that is a p-channel MOSFET, and
wherein the third switch comprises a third FET that is an n-channel MOSFET.

7. The semiconductor device according to claim 4, further comprising:
a second control transistor formed on the semiconductor substrate and configured to control the output transistor to the OFF state by short-circuiting a gate of the output transistor and the reference node in response to a predetermined abnormality detection.

8. The semiconductor device according to claim 1,
wherein the output transistor comprises a vertical n-channel MOSFET having a back surface of the semiconductor substrate as a drain and the power output terminal and the power supply terminal as a source and a drain, respectively,
wherein the first control transistor comprises a horizontal n-channel MOSFET having the reference node and gates of the output transistor as a source and a drain, respectively,
wherein an NPN parasitic bipolar transistor is formed in the first control transistor, and
wherein the parasitic bipolar transistor operates with a back gate of the first control transistor and a source connected to the back gate as a base, and operates with one of the drain of the first control transistor and the back surface of the semiconductor substrate as an emitter and the other as a collector.

9. The semiconductor device according to claim 1,
wherein the reverse current detection circuit comprises a comparator that compares magnitudes of a power supply voltage applied to the power supply terminal and an output voltage generated at the power output terminal.

10. An electronic control system comprising:
a power supply terminal to which a power supply voltage is supplied;
a power output terminal to which a load is connected;
a semiconductor device configured to supply power to the load; and
a control device configured to control the semiconductor device,
wherein the semiconductor device comprises:
an output transistor formed on a semiconductor substrate, and connected between the power supply terminal and the power output terminal, and configured to supply power to the load when being controlled to the ON state;
a first switch configured to connect the power output terminal to a reference node;
a second switch configured to connect the power supply terminal to the reference node;
a first control transistor formed on the semiconductor substrate, and configured to control the output transistor to the OFF state by short-circuiting a gate of the output transistor and the reference node when being controlled to the ON state;
a reverse current detection circuit configured to detect generation of a reverse current from the power output terminal toward the power supply terminal and assert a reverse current detection signal in a period in which the reverse current is generated; and
a switch control circuit configured to control the first switch to the ON state and the second switch to the OFF state in a negation period of the reverse current detection signal, and control the first switch to the OFF state and the second switch to the ON state in an assertion period of the reverse current detection signal, and
wherein the control device outputs an ON/OFF control signal for instructing on/off of the output transistor to the semiconductor device.

11. The electronic control system according to claim 10,
wherein the output transistor comprises an n-channel MOSFET having the power output terminal and the power supply terminal as a source and a drain, respectively,
wherein the first switch comprises a first FET that is an n-channel MOSFET, and
wherein the second switch comprises a second FET that is a p-channel MOSFET.

12. The electronic control system according to claim 11,
wherein the semiconductor device further comprises a fourth FET and a fifth FET connected in series between the power output terminal and the reference node, connected in parallel with the first FET, and both of which are n-channel MOSFETs,
wherein, in the fourth FET, one of a source and a drain is connected to the reference node, the other is connected to an intermediate node, a gate is connected to the intermediate node,
wherein, in the fifth FET, one of a source and a drain is connected to the intermediate node, and the other is connected to the power output terminal,
wherein the first FET and the fifth FET are commonly controlled to be turned on and off by the switch control circuit, and
wherein back gates of the first FET, the fourth FET, and the fifth FET are connected to the intermediate node.

13. The electronic control system according to claim 10,
wherein the semiconductor device further comprises:
an ON/OFF control circuit configured to control on/off of the first control transistor based on an ON/OFF control signal for externally instructing on/off of the output transistor; and
a charge pump circuit configured to generate a boost voltage higher than a power supply voltage applied to the power supply terminal in an active state.

14. The electronic control system according to claim 13,
wherein the semiconductor device further comprises a third switch connected in parallel with the first switch,
wherein the ON/OFF control circuit further controls an active state and an inactive state of the charge pump circuit, and on/off of the third switch,
wherein the switch control circuit controls the first switch to the ON state using the boost voltage, and
wherein the ON/OFF control circuit controls the charge pump circuit in the active state to an inactive state through a predetermined delay time when turn-off of the output transistor is instructed by the ON/OFF control signal, and controls the third switch to the ON state using the power supply voltage.
